(19) United States
(12) Patent Application Publication
(10) Pub. No.: US 2026/0343700 A1
(43) Pub. Date: Oct. 29, 2026

(54) DEVICE CONTROL SYSTEM

(71) Applicant: AIR COOL INDUSTRIAL CO., LTD., Taichung (TW)

(72) Inventor: Shih-Ming Chen, Taichung (TW)

(21) Appl. No.: 19/190,822

(22) Filed: Apr. 28, 2025

(51) Int. Cl. H05B 45/30; G01R 19/175; H03K 5/1536; H05B 45/18

(52) U.S. Cl. CPC H05B 45/30; G01R 19/175; H03K 5/1536; H05B 45/18

(57) ABSTRACT

A device control system, applied to at least one device and a mains power supply, includes a first controller and a second controller. The user can operate the command of the first controller to output a corresponding command signal to the second controller. The second controller compares and reads the command signal to control the at least one device to execute the corresponding command. Thereby, the device control system can be applied to the control of at least one device, thereby reducing manufacturing costs and enhancing convenience of use.

### FIELD OF THE INVENTION

The present invention relates to a control system for a device such as a lamp and a motor, and more particularly to a device control system.

### BACKGROUND OF THE INVENTION

A conventional household appliance, such as a ceiling fan, comprises a motor device. The motor device is electrically connected to an operating switch through a controller. The controller includes a microprocessor chip.

In modern living environments, with the development of household appliances, the demand for controlling a single device or multiple devices has increased accordingly, such as a fan, a fan combined with a lamp, multiple fans, multiple fans combined with multiple lamps, etc. It is obvious that the existing device control system is not as supportive as it could be, and that the cost of the chip is relatively high. Accordingly, the inventor of the present invention has devoted himself based on his many years of practical experiences to solve these problems.

### SUMMARY OF THE INVENTION

The primary object of the present invention is to provide a device control system, which can be applied to the control of at least one device, thereby reducing the flickering of lamps, lowering the manufacturing cost and enhancing the convenience and comfort of use.

In order to achieve the above object, the present invention provides a device control system, applied to at least one device and a mains power supply. The device is a lamp or a motor. The mains power supply outputs an alternating current. The device control system comprises a first controller and a second controller. The first controller includes a switch, a zero-crossing detector, a first power supply unit, a sine wave phase angle control unit, an operation unit, and a first MCU processing unit. The second controller includes a second controller input terminal, a second power supply unit, a power detection circuit, a second MCU processing unit, and at least one driving unit. The switch has an input terminal and an output terminal. The input terminal is electrically connected to the mains power supply for receiving the alternating current. The output terminal is electrically connected to the zero-crossing detector, the first power supply unit and the sine wave phase angle control unit. When the switch is in an ON state, the switch allows the alternating current to be transmitted to the zero-crossing detector, the first power supply unit and the sine wave phase angle control unit. When the switch is in an OFF state, the switch does not output the alternating current. The zero-crossing detector receives the alternating current. The zero-crossing detector detects a zero-crossing of the alternating current to obtain a zero-crossing detection result, thereby enabling the zero-crossing detector to output a signal. The first power supply unit receives and converts the alternating current to output a first direct current. The operation unit is pre-set with at least one command corresponding to the at least one device. One said device corresponds to at least one said command. When a user executes the command of the operation unit, the operation unit outputs a signal. The first MCU processing unit is electrically connected to the zero-crossing detector, the first power supply unit and the operation unit. The first power supply unit outputs the first direct current to the first MCU processing unit for powering the first MCU processing unit to operate. The first MCU processing unit receives the signals output from the zero-crossing detector and the operation unit and obtains the command of the operation unit and the zero-crossing detection result, enabling the first MCU processing unit to output a signal. The sine wave phase angle control unit is electrically connected to the first MCU processing unit. The sine wave phase angle control unit receives the alternating current. The sine wave phase angle control unit outputs at least one command signal. The at least one command corresponds to the at least one command signal. One said command corresponds to one said command signal. When the user does not execute the command of the operation unit, the sine wave phase angle control unit outputs the alternating current. When the user executes the command of the operation unit, the first MCU processing unit outputs the signal to the sine wave phase angle control unit according to the executed command and the zero-crossing detection result, controls the sine wave phase angle control unit to adjust a waveform of the alternating current to form the corresponding command signal, and outputs the corresponding command signal through the sine wave phase angle control unit. The command signal includes at least one main signal segment. A waveform of the main signal segment is composed of at least one cycle of a predefined waveform and a plurality of cycles of sine waves. The sine wave phase angle control unit controls an angle interval in one cycle of the alternating current to be non-conductive, thereby forming the predefined waveform of one said cycle. The second controller input terminal is electrically connected to the sine wave phase angle control unit via a power cord for transmitting the alternating current and the at least one command signal. The second power supply unit is electrically connected to the second controller input terminal to receive and convert the alternating current and output a second direct current. The power detection circuit is electrically connected to the second controller input terminal to receive and convert the at least one command signal and outputs at least one corresponding digital detection signal. The second MCU processing unit is electrically connected to the second power supply unit and the power detection circuit. The second power supply unit outputs the second direct current to the second MCU processing unit for powering the second MCU processing unit to operate. The second MCU processing unit is preset with at least one digital detection signal datum. The at least one command, the at least one command signal, the at least one digital detection signal and the at least one digital detection signal datum correspond to one another. One said command, one said command signal, one said digital detection signal and one said digital detection signal datum correspond to one another. The second MCU processing unit receives the at least one digital detection signal and compares the at least one digital detection signal with the at least one digital detection signal datum. The second MCU processing unit obtains the executed command to output at least one control signal according to a comparison result between the at least one digital detection signal and the at least one digital detection signal datum. The at least one driving unit, the at least one control signal, the at least one device and the at least one command correspond to one another. One said driving unit, at least one said control signal, one said device and at least one said command correspond to one another. The driving unit includes a power processing part and a driving part. The power processing part is electrically connected to the second controller input terminal to receive the alternating current and output a driving power supply. The driving part of the at least one driving unit is electrically connected to the corresponding device, the corresponding power processing part and the second MCU processing unit. The driving part of the at least one driving unit receives the corresponding driving power supply to supply power to the corresponding device. The driving part of the at least one driving unit receives the corresponding control signal. The driving part of the at least one driving unit outputs a signal to the corresponding device according to the corresponding driving power supply and the corresponding control signal, so as to control the corresponding device to execute the corresponding command.

The device control system provided by the present invention can be applied to the control of at least one device, such as a fan, a fan combined with a lamp, multiple fans, or multiple fans combined with multiple lamps, thereby reducing the flickering of lamps, lowering the manufacturing cost and enhancing the convenience and comfort of use.

### BRIEF DESCRIPTION OF THE DRAWINGS

FIG. 1 is a block diagram of a first embodiment of the present invention

FIG. 2 is a signal block diagram of the first embodiment of the present invention;

FIG. 3 is a waveform diagram of the command signal of the first embodiment of the present invention, illustrating the first predefined waveform;

FIG. 4 is a waveform diagram of the command signal of the first embodiment of the present invention, illustrating the second predefined waveform;

FIG. 5 is a waveform diagram of the command signal of a second embodiment of the present invention, illustrating the third predefined waveform; and

FIG. 6 is a waveform diagram of the command signal of the second embodiment of the present invention, illustrating the fourth predefined waveform.

### DETAILED DESCRIPTION OF THE PREFERRED EMBODIMENTS

Embodiments of the present invention will now be described, by way of example only, with reference to the accompanying drawings.

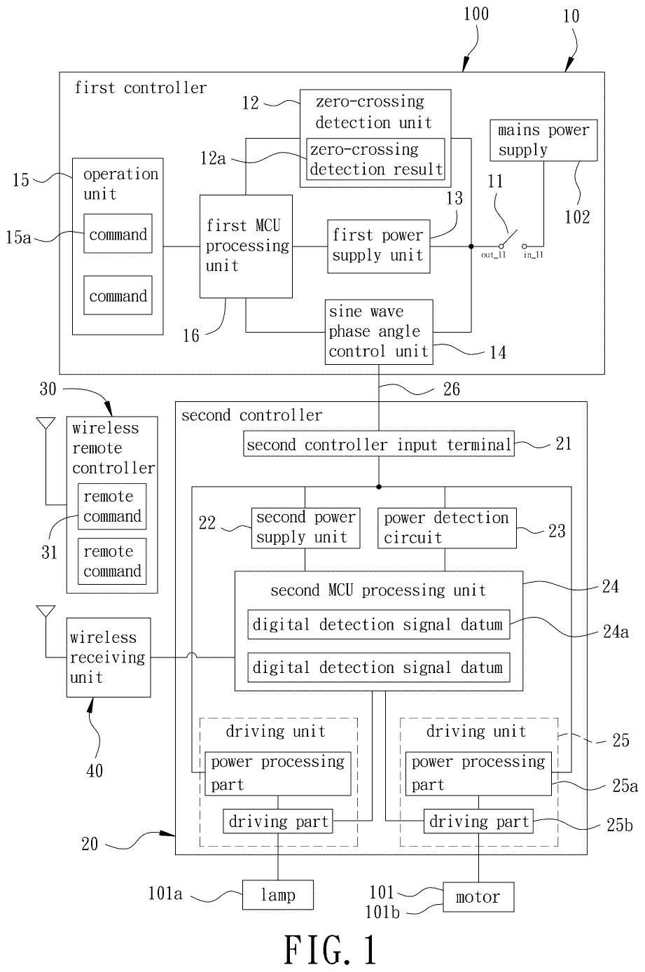

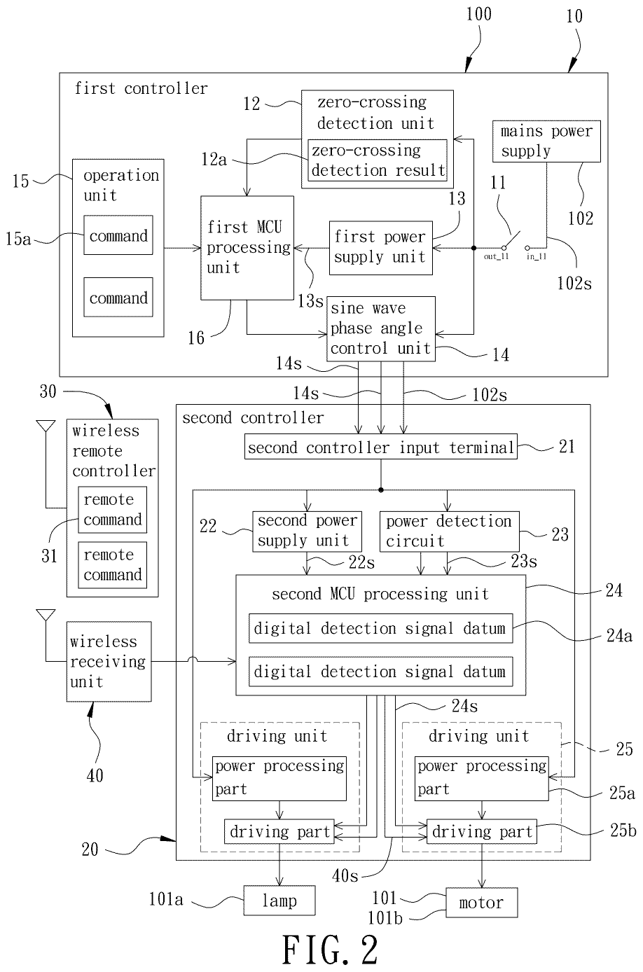

FIG. 1 is a block diagram of a first embodiment of the present invention FIG. 2 is a signal block diagram of the first embodiment of the present invention. The present invention discloses a device control system 100, applied to at least one device 101 and a mains power supply 102. The device 101 may be a lamp 101a or a motor 101b. The at least one device 101 further includes at least two devices 101. The at least two devices 101 include at least one said lamp 101a and at least one said motor 101b. The mains power supply 102 outputs an alternating current 102s. The device control system 100 comprises a first controller 10 and a second controller 20. The first controller 10 includes a switch 11, a zero-crossing detector 12, a first power supply unit 13, a sine wave phase angle control unit 14, an operation unit 15, and a first MCU processing unit 16. The second controller 20 includes a second controller input terminal 21, a second power supply unit 22, a power detection circuit 23, a second MCU processing unit 24, and at least one driving unit 25.

The switch 11 has an input terminal in_11 and an output terminal out_11. The input terminal in_11 is electrically connected to the mains power supply 102 for receiving the alternating current 102s. The output terminal out_11 is electrically connected to the zero-crossing detector 12, the first power supply unit 13 and the sine wave phase angle control unit 14. When the switch 11 is in the ON state, the switch 11 allows the alternating current 102s to be transmitted to the zero-crossing detector 12, the first power supply unit 13 and the sine wave phase angle control unit 14. When the switch 11 is in the OFF state, the switch 11 does not output the alternating current 102s.

The zero-crossing detector 12 receives the alternating current 102s. The zero-crossing detector 12 detects the zero-crossing of the alternating current 102s to obtain a zero-crossing detection result 12a, thereby enabling the zero-crossing detector 12 to output a signal.

The first power supply unit 13 receives and converts the alternating current 102s to output a first direct current 13s.

The operation unit 15 is pre-set with at least one command 15a corresponding to the at least one device 101. One said device 101 corresponds to at least one said command 15a. When the user executes the command 15a of the operation unit 15, the operation unit 15 outputs a signal. The at least one command 15a further has at least two commands 15a. The command 15a related to the motor 101b may be a command to control the operation of the motor, to stop the operation of the motor, to change the direction of rotation of the motor, or to change the speed of the motor. The command 15a related to the lamp 101a may be a command to start the lamp, to change the brightness of the lamp, to change the color temperature of the lamp, or to turn off the lamp.

The first MCU processing unit 16 is electrically connected to the zero-crossing detector 12, the first power supply unit 13 and the operation unit 15. The first power supply unit 13 outputs the first direct current 13s to the first MCU processing unit 16 for powering the first MCU processing unit 16 to operate. The first MCU processing unit 16 receives the signals output from the zero-crossing detector 12 and the operation unit 15 and obtains the command 15a of the operation unit 15 and the zero-crossing detection result 12a, enabling the first MCU processing unit 16 to output a signal.

The sine wave phase angle control unit 14 is electrically connected to the first MCU processing unit 16. The sine wave phase angle control unit 14 receives the alternating current 102s. The sine wave phase angle control unit 14 outputs at least one command signal 14s. The at least one command 15a corresponds to the at least one command signal 14s. One said command 15a corresponds to one said command signal 14s. When the user does not execute the command 15a of the operation unit 15, the sine wave phase angle control unit 14 outputs the alternating current 102s. When the user executes the command 15a of the operation unit 15, the first MCU processing unit 16 outputs the signal to the sine wave phase angle control unit 14 according to the executed command 15a and the zero-crossing detection result 12a, controls the sine wave phase angle control unit 14 to adjust the waveform of the alternating current 102s to form the corresponding command signal 14s, and outputs the corresponding command signal 14s through the sine wave phase angle control unit 14. The command signal 14s includes at least one main signal segment 141. The waveform of the main signal segment 141 is composed of at least one cycle of a predefined waveform 142 and a plurality of cycles of sine waves. The sine wave phase angle control unit 14 controls an angle interval H in one cycle of the alternating current 102s to be non-conductive, thereby forming the predefined waveform of one said cycle. The waveform of the command signal 14s is a voltage waveform. In the two-dimensional voltage-time waveform diagram, time t is displayed on the horizontal axis and voltage v is displayed on the vertical axis. The sine wave phase angle control unit 14 includes electronic components such as a triode AC semiconductor switch (TRIAC), a metal-oxide-semiconductor field-effect transistor (MOSFET), and a diode, and is configured for controlling the conduction angle of the alternating current 102s to output the alternating current 102s and the command signal 14s.

The second controller input terminal 21 is electrically connected to the sine wave phase angle control unit 14 via a power cord 26 for long-distance transmission of the alternating current 102s and the at least one command signal 14s.

The second power supply unit 22 is electrically connected to the second controller input terminal 21 to receive and convert the alternating current 102s and output a second direct current 22s.

The power detection circuit 23 is electrically connected to the second controller input terminal 21 to receive and convert the at least one command signal 14s and outputs at least one corresponding digital detection signal 23s.

The second MCU processing unit 24 is electrically connected to the second power supply unit 22 and the power detection circuit 23. The second power supply unit 22 outputs the second direct current 22s to the second MCU processing unit 24 for powering the second MCU processing unit 24 to operate. The second MCU processing unit 24 is preset with at least one digital detection signal datum 24a. The at least one command 15a, the at least one command signal 14s, the at least one digital detection signal 23s and the at least one digital detection signal datum 24a correspond to one another. One said command 15a, one said command signal 14s, one said digital detection signal 23s and one said digital detection signal datum 24a correspond to one another. The second MCU processing unit 24 receives the at least one digital detection signal 23s and compares the at least one digital detection signal 23s with the at least one digital detection signal datum 24a. The second MCU processing unit 24 obtains the executed command 15a to output at least one control signal 24s according to the comparison result between the at least one digital detection signal 23s and the at least one digital detection signal datum 24a.

The at least one driving unit 25, the at least one control signal 24s, the at least one device 101 and the at least one command 15a correspond to one another. One said driving unit 25, at least one said control signal 24s, one said device 101 and at least one said command 15a correspond to one another. The driving unit 25 includes a power processing part 25a and a driving part 25b. The power processing part 25a is electrically connected to the second controller input terminal 21 to receive the alternating current 102s and output a driving power supply 25s. The driving part 25b of the at least one driving unit 25 is electrically connected to the corresponding device 101, the corresponding power processing part 25a and the second MCU processing unit 24. The driving part 25b of the at least one driving unit 25 receives the corresponding driving power supply 25s to supply power to the corresponding device 101. The driving part 25b of the at least one driving unit 25 receives the corresponding control signal 24s. The driving part 25b of the at least one driving unit 25 outputs a signal to the corresponding device 101 according to the corresponding driving power supply 25s and the corresponding control signal 24s, so as to control the corresponding device 101 to execute the corresponding command 15a.

A wireless remote controller 30 is pre-set with at least one remote control command 31 corresponding to the at least one device 101. One said device 101 corresponds to at least one said remote control command 31. The at least one remote control command 31 further has at least two remote control commands 31. The remote control command 31 related to the motor 101b may be a command to control the operation of the motor, to stop the operation of the motor, to change the direction of rotation of the motor, or to change the speed of the motor. The remote control command 31 related to the lamp 101a may be a command to start the lamp, to change the brightness of the lamp, to change the color temperature of the lamp, or to turn off the lamp.

A wireless receiving unit 40 is electrically connected to the second MCU processing unit 24. The wireless receiving unit 40 is wirelessly connected to the wireless remote controller 30. When the user executes the remote control command 31 of the wireless remote controller 30, the wireless remote controller 30 wirelessly transmits the remote control command 31 of the wireless remote controller 30 to the second MCU processing unit 24 through the wireless receiving unit 40. The second MCU processing unit 24 outputs at least one remote control signal 40s to the driving part 25b of the at least one driving unit 25 according to the remote control command 31 of the wireless remote controller 30. The driving part 25b of the at least one driving unit 25 outputs the signal to the corresponding device 101 according to the driving power supply 25s of the at least one driving unit 25 and the at least one remote control signal 40s, so as to control the corresponding device 101 to execute the corresponding remote control command 31.

Accordingly, when it is desired to increase or decrease the number of devices 101, it is only necessary to adjust the corresponding driving unit 25, the control signal 24s, the command 15a, the remote control command 31, the command signal 14s, and the digital detection signal datum 24a, enabling the present invention to be applied to the control of at least one device 101, such as a fan, a fan combined with a lamp, multiple fans, or multiple fans combined with multiple lamps, thereby reducing the manufacturing cost and enhancing the convenience of use.

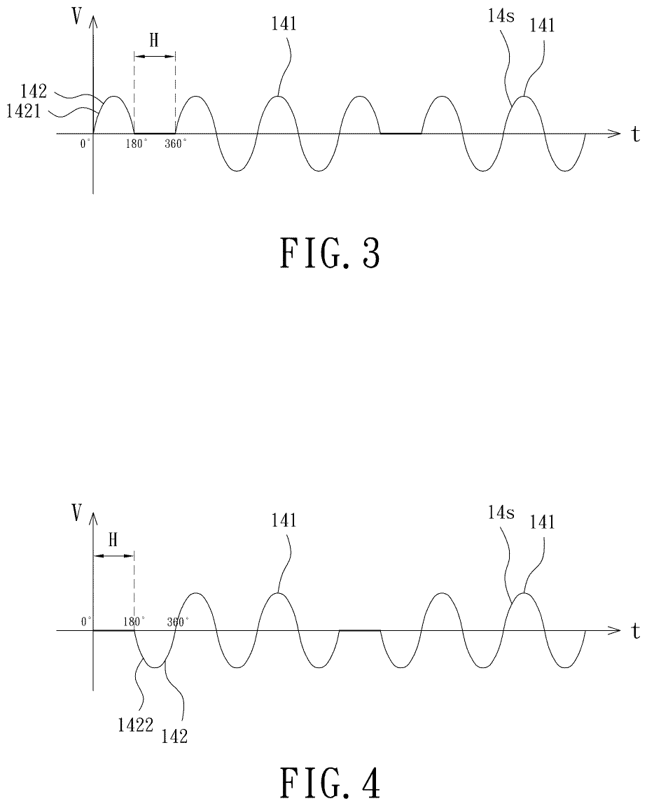

FIG. 3 and FIG. 4 are waveform diagrams showing the command signal 14s of the first embodiment of the present invention. The predefined waveform 142 may be a first predefined waveform 1421 or a second predefined waveform 1422. When the predefined waveform 142 is the first predefined waveform 1421, the angle interval H of non-conduction is from 180 to 360 degrees, as shown in FIG. 3. When the predefined waveform 142 is the second predefined waveform 1422, the angle interval H of non-conduction is from 0 to 180 degrees, as shown in FIG. 4.

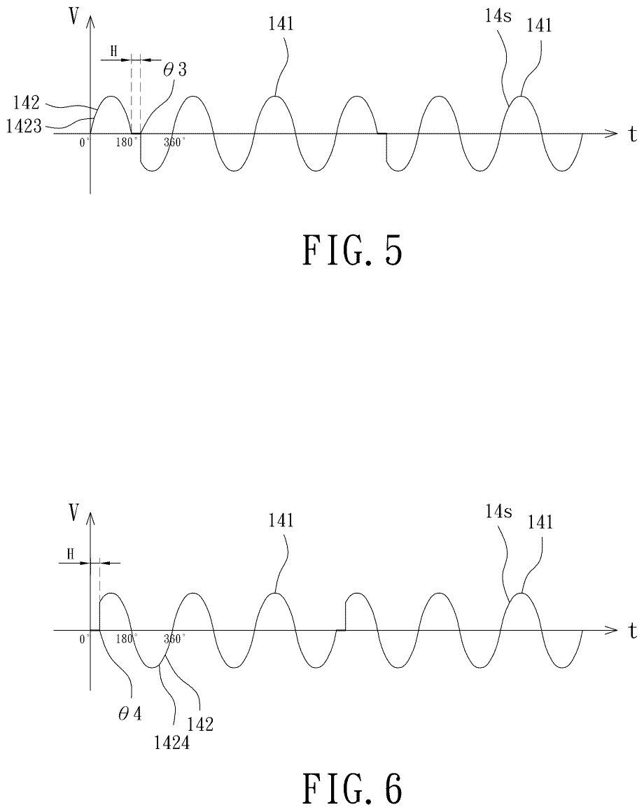

FIG. 5 and FIG. 6 are waveform diagrams showing the command signal 14s of the second embodiment of the present invention. In the second embodiment of the present invention, the predefined waveform 142 may be a third predefined waveform 1423 or a fourth predefined waveform 1424. When the predefined waveform 142 is the third predefined waveform 1423, the angle interval H of non-conduction is from 180 degrees to a third predefined angle θ3, and the third predefined angle θ3 is greater than 180 degrees and less than 360 degrees, as shown in FIG. 5. When the predefined waveform 142 is the fourth predefined waveform 1424, the angle interval H of non-conduction is from 0 degrees to a fourth predefined angle θ4, and the fourth predefined angle θ4 is greater than 0 degrees and less than 180 degrees, as shown in FIG. 6.

When an electrical device includes a motor and a lamp, the noise generated by the operation of the motor will easily interfere with the control of the lamp, affecting the angle interval H of non-conduction and resulting in light flickering. The larger the angle interval H of non-conduction is, the higher the probability of visible flickering to the eyes. The present invention reduces the angle interval H of non-conduction by controlling the third predefined angle θ3 and the fourth predefined angle θ4. When flickering occurs, this shortens the duration of the light flickering, making it imperceptible to the user's eyes and thereby enhancing the comfort of use.

The duration of the predefined waveform 142 in one cycle is greater than 16 milliseconds. The duration of the plurality of cycles of sine waves of the main signal segment 141 is greater than 16 milliseconds.

Although particular embodiments of the present invention have been described in detail for purposes of illustration, various modifications and enhancements may be made without departing from the spirit and scope of the present invention. Accordingly, the present invention is not to be limited except as by the appended claims.

What is claimed is:

1. A device control system, applied to at least one device and a mains power supply, the device being a lamp or a motor, the mains power supply outputting an alternating current, the device control system comprising a first controller and a second controller, the first controller including a switch, a zero-crossing detector, a first power supply unit, a sine wave phase angle control unit, an operation unit and a first MCU processing unit, the second controller including a second controller input terminal, a second power supply unit, a power detection circuit, a second MCU processing unit and at least one driving unit;
wherein the switch has an input terminal and an output terminal, the input terminal is electrically connected to the mains power supply for receiving the alternating current, and the output terminal is electrically connected to the zero-crossing detector, the first power supply unit and the sine wave phase angle control unit, when the switch is in an ON state, the switch allows the alternating current to be transmitted to the zero-crossing detector, the first power supply unit and the sine wave phase angle control unit, when the switch is in an OFF state, the switch does not output the alternating current;
wherein the zero-crossing detector receives the alternating current, the zero-crossing detector detects a zero-crossing of the alternating current to obtain a zero-crossing detection result, thereby enabling the zero-crossing detector to output a signal;
wherein the first power supply unit receives and converts the alternating current to output a first direct current;
wherein the operation unit is pre-set with at least one command corresponding to the at least one device, one said device corresponds to at least one said command, when a user executes the command of the operation unit, the operation unit outputs a signal;
wherein the first MCU processing unit is electrically connected to the zero-crossing detector, the first power supply unit and the operation unit, the first power supply unit outputs the first direct current to the first MCU processing unit for powering the first MCU processing unit to operate, and the first MCU processing unit receives the signals output from the zero-crossing detector and the operation unit and obtains the command of the operation unit and the zero-crossing detection result, enabling the first MCU processing unit to output a signal;
wherein the sine wave phase angle control unit is electrically connected to the first MCU processing unit, the sine wave phase angle control unit receives the alternating current, the sine wave phase angle control unit outputs at least one command signal, the at least one command corresponds to the at least one command signal, one said command corresponds to one said command signal, when the user does not execute the command of the operation unit, the sine wave phase angle control unit outputs the alternating current, when the user executes the command of the operation unit, the first MCU processing unit outputs the signal to the sine wave phase angle control unit according to the executed command and the zero-crossing detection result, controls the sine wave phase angle control unit to adjust a waveform of the alternating current to form the corresponding command signal, and outputs the corresponding command signal through the sine wave phase angle control unit, the command signal includes at least one main signal segment, a waveform of the main signal segment is composed of at least one cycle of a predefined waveform and a plurality of cycles of sine waves, and the sine wave phase angle control unit controls an angle interval in one cycle of the alternating current to be non-conductive, thereby forming the predefined waveform of one said cycle;
wherein the second controller input terminal is electrically connected to the sine wave phase angle control unit via a power cord for transmitting the alternating current and the at least one command signal;
wherein the second power supply unit is electrically connected to the second controller input terminal to receive and convert the alternating current and output a second direct current;
wherein the power detection circuit is electrically connected to the second controller input terminal to receive and convert the at least one command signal and outputs at least one corresponding digital detection signal;
wherein the second MCU processing unit is electrically connected to the second power supply unit and the power detection circuit, the second power supply unit outputs the second direct current to the second MCU processing unit for powering the second MCU processing unit to operate, the second MCU processing unit is preset with at least one digital detection signal datum, the at least one command, the at least one command signal, the at least one digital detection signal and the at least one digital detection signal datum correspond to one another, one said command, one said command signal, one said digital detection signal and one said digital detection signal datum correspond to one another, the second MCU processing unit receives the at least one digital detection signal and compares the at least one digital detection signal with the at least one digital detection signal datum, the second MCU processing unit obtains the executed command to output at least one control signal according to a comparison result between the at least one digital detection signal and the at least one digital detection signal datum;
wherein the at least one driving unit, the at least one control signal, the at least one device and the at least one command correspond to one another, one said driving unit, at least one said control signal, one said device and at least one said command correspond to one another, the driving unit includes a power processing part and a driving part, the power processing part is electrically connected to the second controller input terminal to receive the alternating current and output a driving power supply, the driving part of the at least one driving unit is electrically connected to the corresponding device, the corresponding power processing part and the second MCU processing unit, the driving part of the at least one driving unit receives the corresponding driving power supply to supply power to the corresponding device, the driving part of the at least one driving unit receives the corresponding control signal, the driving part of the at least one driving unit outputs a signal to the corresponding device according to the corresponding driving power supply and the corresponding control signal, so as to control the corresponding device to execute the corresponding command.

2. The device control system as claimed in claim 1, wherein the predefined waveform is one of a first predefined waveform and a second predefined waveform, when the predefined waveform is the first predefined waveform, the angle interval of non-conduction is from 180 to 360 degrees, when the predefined waveform is the second predefined waveform, the angle interval of non-conduction is from 0 to 180 degrees.

3. The device control system as claimed in claim 1, wherein the predefined waveform is one of a third predefined waveform and a fourth predefined waveform, when the predefined waveform is the third predefined waveform, the angle interval of non-conduction is from 180 degrees to a third predefined angle, and the third predefined angle is greater than 180 degrees and less than 360 degrees, when the predefined waveform is the fourth predefined waveform, the angle interval of non-conduction is from 0 degrees to a fourth predefined angle, and the fourth predefined angle is greater than 0 degrees and less than 180 degrees.

4. The device control system as claimed in claim 1, wherein a waveform of the command signal is a voltage waveform.

5. The device control system as claimed in claim 1, wherein the at least one device further includes at least two devices, the at least two devices include at least one said lamp and at least one said motor, the at least one command further has at least two commands, the command related to the motor is a command to control operation of the motor, to stop operation of the motor, to change a direction of rotation of the motor or to change a speed of the motor, and the command related to the lamp is a command to start the lamp, to change brightness of the lamp, to change a color temperature of the lamp or to turn off the lamp.

6. The device control system as claimed in claim 1, further comprising a wireless remote controller and a wireless receiving unit, wherein the wireless remote controller is pre-set with at least one remote control command corresponding to the at least one device, one said device corresponds to at least one said remote control command;
wherein the wireless receiving unit is electrically connected to the second MCU processing unit, the wireless receiving unit is wirelessly connected to the wireless remote controller, when the user executes the remote control command of the wireless remote controller, the wireless remote controller wirelessly transmits the remote control command of the wireless remote controller to the second MCU processing unit through the wireless receiving unit, the second MCU processing unit outputs at least one remote control signal to the driving part of the at least one driving unit according to the remote control command of the wireless remote controller, and the driving part of the at least one driving unit outputs the signal to the corresponding device according to the driving power supply of the at least one driving unit and the at least one remote control signal, so as to control the corresponding device to execute the corresponding remote control command.

7. The device control system as claimed in claim 6, wherein the at least one device further includes at least two devices, the at least two devices include at least one said lamp and at least one said motor, the at least one command further has at least two commands, the command related to the motor is a command to control operation of the motor, to stop operation of the motor, to change a direction of rotation of the motor or to change a speed of the motor, the command related to the lamp is a command to start the lamp, to change brightness of the lamp, to change a color temperature of the lamp or to turn off the lamp, the at least one remote control command further has at least two remote control commands, the remote control command related to the motor is a command to control operation of the motor, to stop operation of the motor, to change the direction of rotation of the motor or to change the speed of the motor, and the remote control command related to the lamp is a command to start the lamp, to change brightness of the lamp, to change the color temperature of the lamp or to turn off the lamp.

8. The device control system as claimed in claim 3, wherein the at least one device further includes at least two devices, the at least two devices include at least one said lamp and at least one said motor, the at least one command further has at least two commands, the command related to the motor is a command to control operation of the motor, to stop operation of the motor, to change a direction of rotation of the motor or to change a speed of the motor, and the command related to the lamp is a command to start the lamp, to change brightness of the lamp, to change a color temperature of the lamp or to turn off the lamp.

9. The device control system as claimed in claim 1, wherein a duration of the predefined waveform in one cycle is greater than 16 milliseconds, and a duration of the plurality of cycles of sine waves of the main signal segment is greater than 16 milliseconds.

10. The device control system as claimed in claim 1, wherein the sine wave phase angle control unit includes a triode AC semiconductor switch (TRIAC), a metal-oxide-semiconductor field-effect transistor (MOSFET) and a diode, and is configured for controlling a conduction angle of the alternating current to output the alternating current and the command signal.
